(19) United States
(12) Patent Application Publication
(10) Pub. No.: US 2026/0025907 A1
(43) Pub. Date: Jan. 22, 2026

(54) POWER MODULE USING TERMINALS OF PASSIVE COMPONENT AS VIAS

(71) Applicant: Monolithic Power Systems, Inc., Kirkland, WA (US)

(72) Inventors: Ting GE, San Jose, CA (US); Yingjiang PU, Chengdu (CN); Eric NGUYEN, Bellevue, WA (US)

(21) Appl. No.: 19/265,961

(22) Filed: Jul. 10, 2025

Related U.S. Application Data
(60) Provisional application No. 63/673,148, filed on Jul. 18, 2024.

(51) Int. Cl. H05K 1/02; H05K 1/11; H05K 1/18

(52) U.S. Cl. CPC H05K 1/0204; H05K 1/117; H05K 1/181; H05K 2201/10015; H05K 2201/1003; H05K 2201/10053

(57) ABSTRACT

A passive component assembly has a substrate and a passive block. The passive block has a top surface and a bottom surface which is opposite to the top surface. The passive block is mounted on the substrate, and a plurality of pads are exposed on the top surface. The passive block has a plurality of capacitors. A top side of at least one terminal of the plurality of capacitors extends to the top surface to form one of the plurality of pads, and a bottom side of the at least one terminal of the plurality of capacitors extends to the bottom surface to be attached to the substrate.

### CROSS-REFERENCE TO RELATED APPLICATIONS

The present application claims the benefit of U.S. Provisional Application No. 63/673,148, filed on Jul. 18, 2024, which is incorporated herein by reference in its entirety.

### BACKGROUND OF THE INVENTION

### 1. Field of the Invention

The present invention generally relates to electrical components, and more particularly but not exclusively relates to power module.

### 2. Description of Related Art

Power converter, as known in the art, converts an input power to an output power for providing a load with required voltage and current. Multi-phase power converter comprising a plurality of paralleled power stages operating out of phase has lower output ripple voltage, better transient performance and lower ripple-current-rating requirements for input capacitors. They are widely used in high current and low voltage applications, such as server and microprocessor.

With the development of modern GPUs (Graphics Processing Units), and CPUs (Central Processing Units), increasingly high load current is required to achieve better processor performance. However, higher current and smaller size put more challenges to the heat conduction. Therefore, it is desirable to provide a power module with high-power density, high-efficiency and excellent heat dissipation capability in space-constrained environments.

### SUMMARY OF THE INVENTION

In one embodiment, a passive component assembly comprises a substrate and a passive block. The passive block has a top surface and a bottom surface which is opposite to the top surface. The passive block is mounted on the substrate, and a plurality of pads are exposed on the top surface. The passive block has a plurality of capacitors. Each of the plurality of capacitors has two terminals, a top side of at least one terminal of the plurality of capacitors extends to the top surface to form one of the plurality of pads, and a bottom side of the at least one terminal of the plurality of capacitors extends to the bottom surface to be attached to the substrate.

In another embodiment, a power module has a power block and a passive component assembly. The power block has a pair of switches and an output inductor. The output inductor has a first end coupled to a switch node formed by the pair of switches and a second end coupled to an output node of the power module. The passive component assembly is attached to the power block. The passive component assembly comprises a passive block having a plurality of capacitors. Terminals of at least one of the plurality of capacitors are configured as vias to conduct current for the power block.

In yet another embodiment, a power supply system has a motherboard, a load and a power module. The motherboard has a first side and a second side. The load is mounted on the first side of the motherboard. The power module is attached to the second side of the motherboard, and provides an output voltage to the load at an output node. The power module comprises a passive component assembly and a power block. The passive component assembly has a top surface and a bottom surface opposite the top surface. The bottom surface faces towards the second side of the motherboard, the passive component assembly comprises a plurality of capacitors. The power block is placed on the top surface of the passive component assembly. Terminals of the plurality of capacitors are configured as vias to conduct current between the power block and the motherboard.

These and other features of the present disclosure will be readily apparent to persons of ordinary skill in the art upon reading the entirety of this disclosure, which includes the accompanying drawings and claims.

### BRIEF DESCRIPTION OF DRAWINGS

The present invention can be further understood with reference to the following detailed description and the appended drawings, wherein like elements are provided with like reference numerals. These drawings are only for illustration purpose, thus may only show part of the devices and are not necessarily drawn to scale.

FIG. 1 shows a schematic diagram of a hybrid buck converter 100 in accordance with an embodiment of the present invention.

FIG. 2 shows a passive component assembly 20 for a power converter in accordance with an embodiment of the present invention.

FIG. 3 shows a perspective view illustrating the passive component assembly 20 of FIG. 2 in accordance with an embodiment of the present invention.

FIG. 4A shows a cross-sectional view illustrating the passive component assembly 20 taken along AA′ line of FIG. 2 in accordance with an embodiment of the present invention.

FIG. 4B shows a cross-sectional view illustrating the passive component assembly 20 taken along AA′ line of FIG. 2 in accordance with another embodiment of the present invention.

FIG. 4C shows a three-dimensional (3D) view of a capacitor 41 in accordance with an embodiment of the present invention.

FIG. 5 shows a top view illustrating the passive component assembly 20 of FIG. 2 in accordance with an embodiment of the present invention.

FIG. 6 shows a capacitor 60 in accordance with an embodiment of the present invention.

FIG. 7 shows a cross-sectional view illustrating the capacitor 60 taken along BB′ line of FIG. 6 in accordance with an embodiment of the present invention.

FIG. 8 shows a capacitor 80 in accordance with an embodiment of the present invention.

FIG. 9 shows a cross-sectional view illustrating the capacitor 80 taken along CC′ line of FIG. 8 in accordance with an embodiment of the present invention.

FIG. 10 shows a power module 300 using a passive component assembly in accordance with an embodiment of the present invention.

FIG. 11 shows a disassembled and perspective view illustrating a power block 3001 of FIG. 10.

FIG. 12 shows a cross-sectional view illustrating the power module 300 taken along DD′ line of FIG. 10 in accordance with an embodiment of the present invention.

FIG. 13 shows a bottom view 130 of the bottom substrate 301, i.e., the second surface 301-b of the bottom substrate 301, in accordance with an embodiment of the present invention.

FIG. 14 shows a cross-sectional view illustrating a passive component assembly 140 in accordance with another embodiment of the present invention.

FIG. 15 shows a top view illustrating the passive component assembly 140 of FIG. 14 in accordance with an embodiment of the present invention.

FIG. 16 shows a cross-sectional view illustrating a passive component assembly 150 in accordance with yet another embodiment of the present invention.

FIGS. 17-19 shows a process of fabricating a passive component assembly in accordance with an embodiment of the present invention.

FIG. 20 shows a side view of a physical layout of a power supply system 900 in accordance with an embodiment of the present invention.

### DETAILED DESCRIPTION OF THE INVENTION

In the present disclosure, numerous specific details are provided, such as examples of electrical circuits and components, to provide a thorough understanding of embodiments of the invention. Persons of ordinary skill in the art will recognize, however, that the invention can be practiced without one or more of the specific details. It is noted that, for purposes of illustrative clarity, certain elements in the drawings may not be drawn to scale. In other instances, well-known details are not shown or described to avoid obscuring aspects of the invention.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

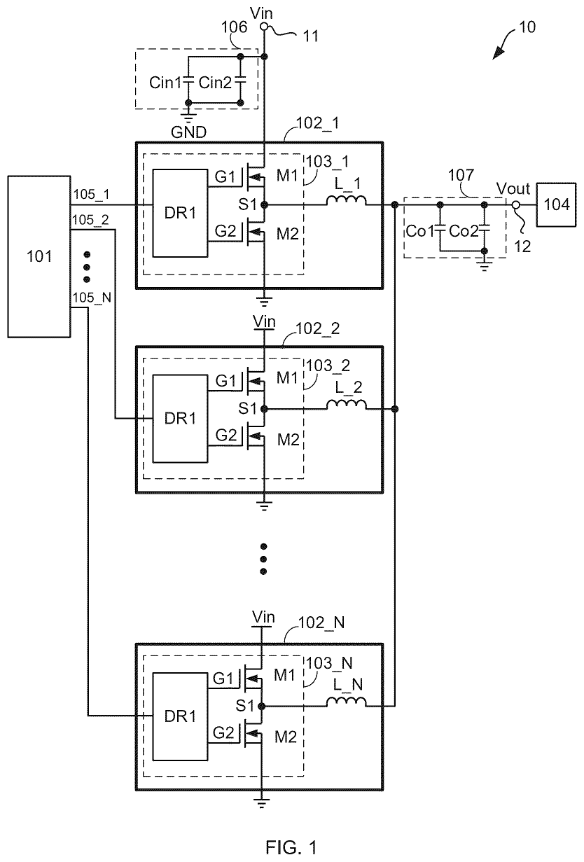

FIG. 1 schematically shows a multi-phase power converter 10 in accordance with an embodiment of the present invention. The multi-phase power converter 10 comprises an input node 11, an output node 12, an input capacitor pack 106, an output capacitor pack 107, a controller 101, N power packs 103_1-103_N and N output inductors L_1-L_N for supplying power to a load 104, wherein N is an integer, and N≥1. The input node 11 is configured to receive an input voltage Vin, and the output node 12 is configured to provide an output voltage Vout. The input capacitor pack 106 has a plurality of input capacitors coupled in parallel between the input node 11 and a reference ground GND. The embodiment of FIG. 1 shows four input capacitors Cin1-Cin2 as one example. However, one with ordinary skill in the art should understand that the number of the input capacitors are not limited by FIG. 1, more or less input capacitors could be included. The output capacitor 107 has a plurality of output capacitors coupled in parallel between the output node 12 and the reference ground GND. The embodiment of FIG. 1 shows four input capacitors Co1-Co2 as one example. However, one with ordinary skill in the art should understand that the number of the input capacitors are not limited by FIG. 1, more or less output capacitors could be included.

Each power pack 103 and one inductor L represent one power stage, i.e., one phase 102 of the power converter 10, as shown in FIG. 1. Each power pack 103 includes switches M1, M2 and a driver DR1 for providing driving signals G1 and G2 to drive the switches M1 and M2 respectively. The controller 101 provides N phase control signals 105_1-105_N respectively to N power packs 103_1-103_N to control the N phases 102_1-102_N working out of phase, e.g., the output inductors L_1-L_N sequentially deliver power to the load 104. It should be noticed that the outputs of all phases as shown in FIG. 1 are connected to work as a multi-phase converter. However, each phase output may be separated to work as multiple independent converters which could have different output voltage levels for different load demands. The output inductors L_1-L_N could be implemented by one or a few coupled inductors or could be implemented by N independent inductors. When N=2, the multi-phase power converter 10 is used as a dual-phase power converter or two separate single-phase converters. For the ease of description, dual-phase power module for a dual-phase power converter is discussed as an example to illustrate the present invention.

The power stage 102 with Buck topology is shown in FIG. 1 for example. Persons of ordinary skill in the art should appreciate that power stages with other topologies, like Boost topology, Buck-Boost topology could also be adopted in a multi-phase power converter.

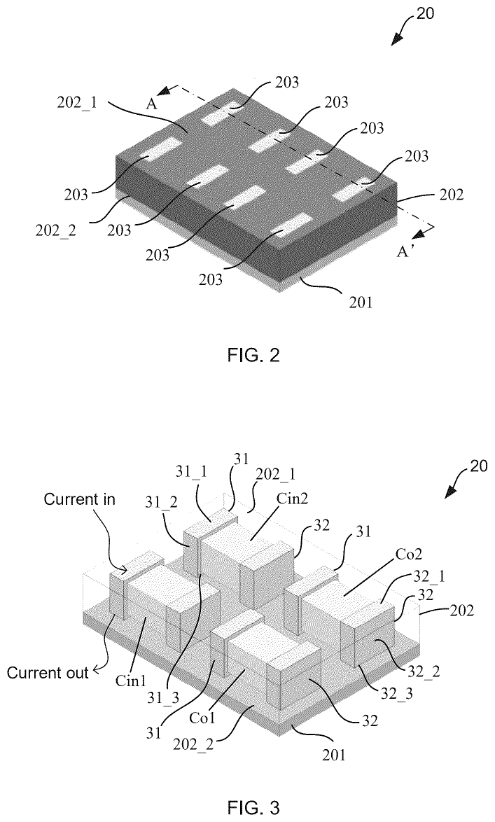

FIG. 2 shows a passive component assembly 20 for a power converter in accordance with an embodiment of the present invention. The passive component assembly 20 comprises a substrate 201 and a passive block 202 mounted on the substrate 201. The substrate may comprise a printed circuit board (PCB), an interposer for metal interconnects, a base board that support components embedded in or be mounted on its surface, or any other suitable forms. In one embodiment, a plurality of passive components, such as the input capacitor pack 106 and the output capacitor pack 107, are embedded in the passive block 202, e.g., with or without molding. The passive block 202 has a top surface 202_1 and a bottom surface 202_2 opposite to the top surface 202_1. The top surface 202_1 is also as a top surface of the passive component assembly 20, which can be electrically connected to other components (such as a power block or another substrate) via a plurality of pad 203 exposed on the top surface 202_1. In one embodiment, the plurality of pads 203 are formed by terminals of passive components, e.g., terminals of the input capacitors Cin1-Cin2, and terminals of the output capacitors Co1-Co2. In one embodiment, the terminals of passive components are configured as vias to conduct current, e.g., between the top surface 202_1 and the substrate 201.

FIG. 3 shows a perspective view illustrating the passive component assembly 20 of FIG. 2 in accordance with an embodiment of the present invention. The embodiment of FIG. 3 shows the input capacitors Cin1-Cin2 and the output capacitors Co1-Co2 in the passive block 202. One with ordinary skill in the art should understand that the number of capacitors is not limited by embodiments of FIGS. 2-3 shown, any other suitable number of capacitors could be included in the passive block 202.

As shown in FIG. 3, each capacitor has a terminal 31 and a terminal 32, each terminal 31 has a top side 31_1, a middle side 31_2, and a bottom side 31_3, and each terminal 32 has a top side 32_1, a middle side 32_2, and a bottom side 32_3. The top side 31_1 of each terminal 31 and the top side 32_1 of each terminal 32 are extended to the top surface 202_1 to form the pads 203, the bottom side 31_3 of each terminal 31 and the bottom side 32_3 of each terminal 32 are extended to the bottom surface 202_2 to be attached to the substrate 201. The middle side 31_2 of each terminal 31 is between the top side 31_1 and the bottom side 31_3, and the middle side 32_2 of each terminal 32 is between the top side 32_1 and the bottom side 32_3. Each terminal 31 and each terminal 32 could be used to conduct current. Take the terminal 31 as one example, a current could flow in from the top side 31_1, flow through the middle side 31_2, and flow out from the bottom side 31_3. In another example, the current could also flow in from the bottom side 31_3, flow through the middle side 31_2, and flow out from the top side 31_1.

Embodiments of the present invention use terminals of passive components as vias to conduct current, so the space is fully utilized. Traditionally, copper pillar is used to form current conduction path, the capacitor quantity is limited because of space limited, and the power density is low. By using the passive block 202, most of the space can be used to place capacitors, and the current allowed to flow through terminals of the capacitors is larger than traditional.

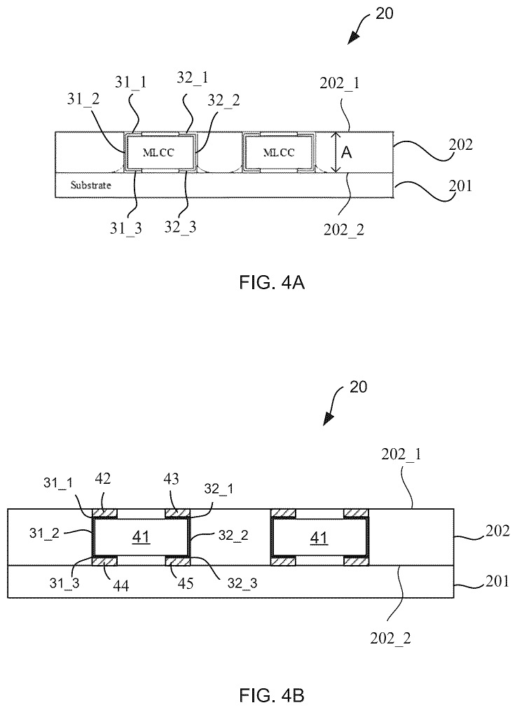

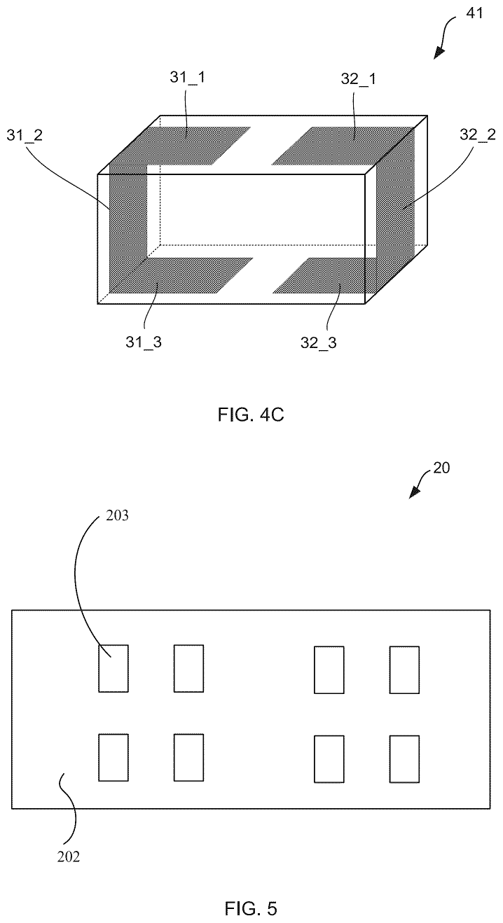

FIG. 4A shows a cross-sectional view illustrating the passive component assembly 20 taken along AA′ line of FIG. 2 in accordance with an embodiment of the present invention. The capacitors shown in FIG. 4A takes multi-layer ceramic capacitors (MLCC) as one example, one with ordinary skill in the art should understand that other type of capacitor could also be used. As shown in FIG. 4A, the terminals 31 and 32 are extended between the top surface 202_1 and the bottom surface 202_2 of the passive block 202. Specifically, the terminals 31 and 32 are extended to the top surface 202_1 to form at least part of the plurality of pads 203. In one embodiment, height A of the capacitor is about 0.4 mm to 0.6 mm, typically 0.5 mm. In the embodiment of FIG. 4A, the top side 31_1 of the terminal 31 and the top side 32_1 of the terminal 32 form one of the pads 203 respectively, while the bottom side 31_3 of the terminal 31 and the bottom side 32_3 of the terminal 32 are attached to the substrate 201 respectively.

FIG. 4B shows a cross-sectional view illustrating the passive component assembly 20 taken along AA′ line of FIG. 2 in accordance with another embodiment of the present invention. In the example of FIG. 4B, the passive component assembly 20 has a plurality of capacitors 41, each has terminals 31 and 32. The top side 31_1 of the terminal 31 shown in FIG. 4B extends to the top surface 202_1 through a connector 42 to form one of the pads 203. The top side 32_1 of the terminal 32 shown in FIG. 4B extends to the top surface 202_1 through a connector 43 to form one of the pads 203. The bottom side 31_3 of the terminal 31 shown in FIG. 4B extends to the bottom surface 202_2 through a connector 44 to attach to the substrate 201. The bottom side 32_3 of the terminal 32 shown in FIG. 4B extends to the bottom surface 202_2 through a connector 45 to be attached to the substrate 201. The connectors 42-45 may be formed via electroplating or soldering.

FIG. 4C shows a three-dimensional (3D) view of the capacitor 41 in accordance with an embodiment of the present invention. In one embodiment, a thickness of the top sides 31_1 and 32_1 as measured perpendicular to the top surface 202-1 (referring FIG. 4B) is less than 0.03 mm, and a thickness of the bottom sides 31_3 and 32_3 as measured perpendicular to the bottom surface 202-2 (referring FIG. 4B) is less than 0.03 mm

FIG. 5 shows a top view illustrating the passive component assembly 20 of FIG. 2 in accordance with an embodiment of the present invention. As shown in FIG. 5, a plurality of pads 203 are exposed, and only one 203 is labelled in FIG. 5 for clarity. In one embodiment, the exposed pads 203 comprises copper.

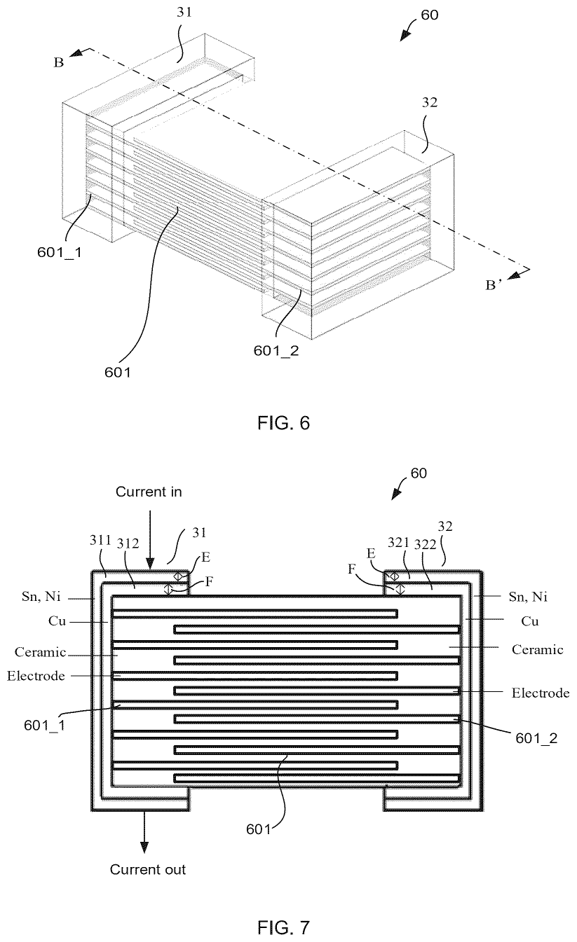

FIG. 6 shows a capacitor 60 in accordance with an embodiment of the present invention. The capacitor 60 is an embodiment of the capacitor (e.g., one of the input capacitors or one of the output capacitors) included in the passive block 202. In the embodiment of FIG. 6, the capacitor 60 has a plurality of horizontally stacked copper layers 601 parallel to the top surface 202_1 and the bottom surface 202_2 of the passive block 202. A first group 601_1 of the horizontally stacked copper layers 601 are electrically connected to the terminal 31, and a second group 601_2 of the horizontally stacked copper layers 601 are electrically connected to the terminal 32.

FIG. 7 shows a cross-sectional view illustrating the capacitor 60 taken along BB′ line of FIG. 6 in accordance with an embodiment of the present invention. The horizontally stacked copper layers 601 is used as electrode of the capacitor 60, and an insulating material, e.g., ceramic, is filled between each of the horizontally stacked copper layers 601. In the embodiment of FIG. 7, the terminal 31 has an outer portion 311 and an inner portion 312, the terminal 32 has an outer portion 321 and an inner portion 322. The inner portion 312 made of a first metal material, e.g., Cu, is enveloped by the outer portions 311 which is made of a second metal material, e.g., Sn, Ni. The inner portion 322 made of the first metal material, e.g., Cu, is enveloped by the outer portions 321 which is made of the second metal material, e.g., Sn, Ni. In one embodiment, the first metal material which forms the inner portions 312 and 322 has higher conductivity than the second metal material which forms the outer portions 311 and 321. In one embodiment, a thickness F of the inner portions 312 and 322 as measured perpendicular to the top surface 202-1 of the passive block 202 is from 0.03 mm to 0.1 mm, and a thickness E of the outer portions 311 and 321 as measured perpendicular to the top surface 202-1 of the passive block 202 is from 0.03 mm to 0.1 mm. In one embodiment, a first current flows into the terminal 31 at the top side, and flows through the portions 311 and 312, and then flows out of the terminal 31 from the bottom side as shown in FIG. 7. Similarly, one with ordinary skill in the art should understand that the first current could also flow into the terminal at the bottom side, flow through the portions 311 and 312 and flow out of the terminal from the top side. In one embodiment, a second current flows into the terminal 32 at the top side, and flows through the portions 321 and 322, and then flows out of the terminal 32 from the bottom side. In another embodiment, the second current flows into the terminal 32 at the bottom side, and flows through the portions 321 and 322, and then flows out of the terminal 32 from the top side.

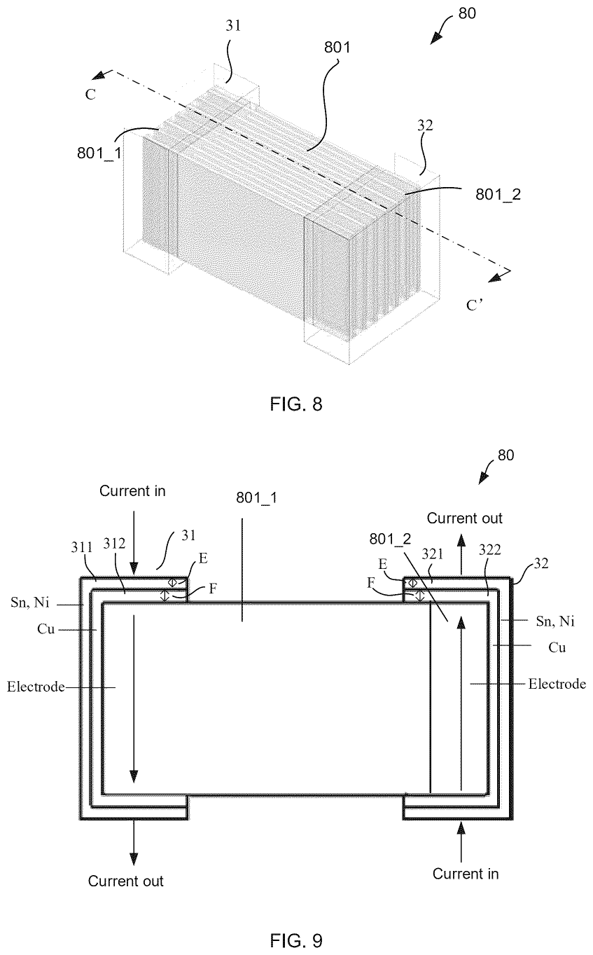

FIG. 8 shows a capacitor 80 in accordance with an embodiment of the present invention. The capacitor 80 is another embodiment of the capacitor (e.g., one of the input capacitors or one of the output capacitors) included in the passive block 202. In the embodiment of FIG. 8, the capacitor 80 has a plurality of vertically stacked copper layers 801 perpendicular to the top surface 202_1 and the bottom surface 202_2 of the passive block 202. A first group 801_1 of the vertically stacked copper layers 801 are electrically connected to the terminal 31, and a second group 801_2 of the vertically stacked copper layers 801 are electrically connected to the terminal 32. The insulating material, e.g., ceramic, is filled between each of the vertically stacked copper layers 801. With the vertically stacked copper layers 801, an impedance between top and bottom of the capacitor 80 is reduced. And the vertically stacked copper layers 801 further provides current conduct paths between top and bottom.

FIG. 9 shows a cross-sectional view illustrating the capacitor 80 taken along CC′ line of FIG. 8 in accordance with an embodiment of the present invention. In the embodiment show in FIG. 9, the current flows into the terminal 31 at the top side, flows through the portions 311-312 and the first group 801_1 of the vertically stacked copper layers 801, and flows out of the terminal 31 from the bottom side. In one embodiment, another current could flow into the terminal 32 at the bottom side, flow through the portions 321-322 and the second group 801_2 of the vertically stacked copper layers 801, and flow out of the terminal 32 from the top side. One with ordinary skill in the art should also understand that the current direction shown in FIG. 9 is for illustrated and not limited, the current direction may be different from the embodiment of FIG. 9.

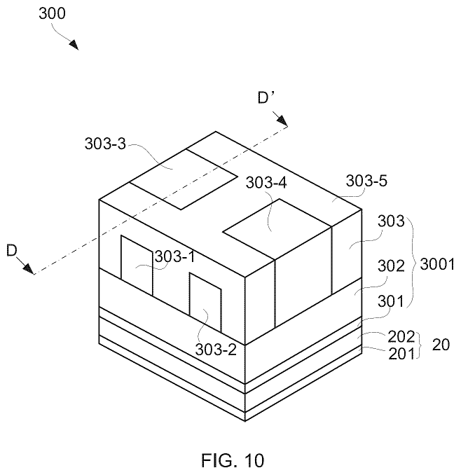

FIG. 10 shows a power module 300 using the passive component assembly 20 in accordance with an embodiment of the present invention. In the embodiment of FIG. 10, the power module 300 comprise a dual-phase power converter of FIG. 1, with N=2, for illustration purpose. One with ordinary skill in the art should understand that the phase number is not limited by the embodiment of FIG. 10. In one embodiment, the power module 300 has a power block 3001 and the passive component assembly 20. In the embodiment of FIG. 10, the power block 3001 comprises a bottom substrate 301, a device substrate 302, and an inductor assembly 303. The bottom substrate 301 is arranged at the bottom of the power block 3001. The device substrate 302 is arranged on the bottom substrate 301. The inductor assembly 303 is arranged on the device substrate 302. At least one power device die integrating the components of the power packs 103 shown in FIG. 1 is embedded within the device substrate 302. The output inductors L are integrated in the inductor assembly 303.

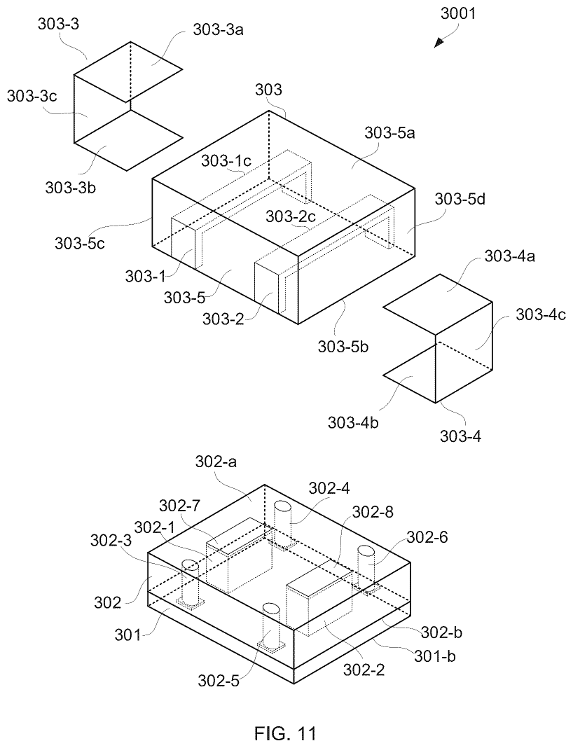

FIG. 11 shows a disassembled and perspective view illustrating the power block 3001 of FIG. 10. As shown in FIG. 11, the device substrate 302 includes a first power device die 302-1, a second power device die 302-2, a first pair of connecting pillars 302-3 and 302-4, a second pair of connecting pillars 302-5 and 302-6. Each one of the first power device die 302-1 and the second power device die 302-2 integrates one power pack 103 in FIG. 1, which includes the switches M1, M2, the driver DR1, and further integrates some auxiliary circuits not shown in FIG. 1. The first pair of the connecting pillars includes a first connecting pillar 302-3 and a second connecting pillar 302-4 arranged at opposite sides of the first power device die 302-1. The second pair of the connecting pillars include a third connecting pillar 302-5 and a fourth connecting pillar 302-6 arranged at opposite sides of the second power device die 302-2. Each one of the connecting pillars has a first end connecting out of the device substrate 302 and connected to the corresponding winding of the inductor assembly 303, and a second end connected to the bottom substrate 301. The connecting pillars shown in the example of FIG. 11 are cylinders. It should be appreciated that any shape of the connecting pillars is applicable to the present invention.

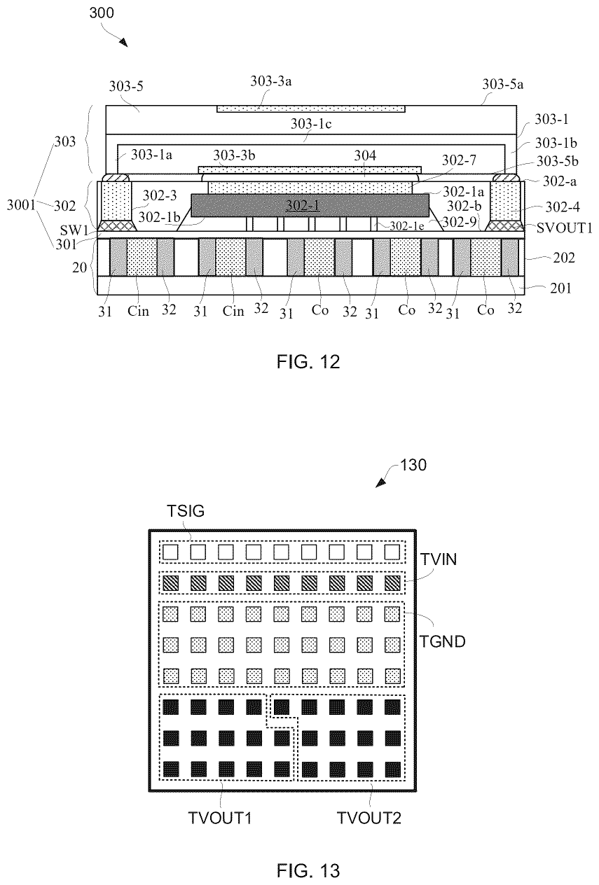

In the example of FIG. 11, the inductor assembly 303 includes a magnetic core 303-5, a first winding 303-1 and a second winding 303-2 passing through the magnetic core 303-5. The first winding 303-1 and the magnetic core 303-5 form a first inductor L-1 as shown in FIG. 1. The second winding 303-2 and the magnetic core 303-5 form a second inductor L-2 as shown in FIG. 1. Furthermore, the inductor assembly 303 includes a first heat sink layer 303-3 and a second heat sink layer 303-4, each of which has a “C” shape, and partially wraps the magnetic core 303-5. As can be seen from FIG. 11, the first heat sink layer 303-3 has a first portion 303-3a partially covering a first surface 303-5a of the magnetic core 303-5, a second portion 303-3b partially covering a second surface 303-5b of the magnetic core 303-5, and a third portion 303-3c connecting the first portion 303-3a and the second portion 303-3b, and partially covering a third surface 303-5c of the magnetic core 303-5, wherein the first surface 303-5a and the second surface 303-5b are opposite, and the third surface 303-5c is vertical to the first surface 303-5a and the second surface 303-5b. The second heat sink layer 303-4 has a first portion 303-4a partially covering the first surface 303-5a, a second portion 303-4b partially covering the second surface 303-5b, and a third portion 303-4c connecting the first portion 303-4a and the second portion 303-4b, and covering a fourth surface 303-5d of the magnetic core 303-5, wherein the fourth surface 303-5d is opposite to the third surface 303-5c, and is vertical to the first surface 303-5a and the second surface 303-5b of the magnetic core 303-5. The surfaces of the magnetic core 303-5 are also referred as surfaces of the inductor assembly 303. It should be appreciated that the first heat sink layer 303-3 and the second heat sink layer 303-4 are configured for transferring heat from the power device dies to the environment or external components. The shape of the first heat sink layer 303-3 and the second heat sink layer 303-4 may be varying in different applications, e.g., the first heat sink layer 303-3 may have a “L” shape with the second portion 303-3b and the third portion 303-3c, and similarly, the second heat sink layer 303-4 may have a “L” shape with the second portion 303-4b and the third portion 303-4c. The second portion 303-3b of the first heat sink layer 303-3 partially covers the second surface 303-5b of the magnetic core 303-5 and is attached to the top heat layer 302-7 directly or via a heat conductive contact 304 as shown in the example of FIG. 12. In one embodiment, the heat sink layers 303-3 and 303-4 are made of copper and dissipate heat from the top heat layers on top of the power device dies 302-1 and 302-2. Consequently, the heat of the power device dies 302-1 and 302-2 are dissipated via the top heat layers 302-7 and 302-8 and the heat sink layer 303-3 and 303-4, respectively. The heat sinks 303-3 and 303-4 are attached to the magnetic core 303-5 by either thermal glue, thermal paste, or direct contact.

FIG. 12 shows a cross-sectional view illustrating the power module 300 taken along DD′ line of FIG. 10 in accordance with an embodiment of the present invention.

As shown in FIG. 12, the first power device die 302-1 has a first surface 302-1a and a second surface 302-1b. The first surface 302-1a is partially covered by a top heat layer 302-7, and the second surface 302-1b has a plurality of pins 302-1e exposed on the second surface 302-b of the device substrate 302, and connected to the bottom substrate 301. It should be appreciated that the pins 302-1e shown in FIG. 12 are for illustration purpose. More pins may be configured in a real application. Furthermore, the pin shape, the pin size and the pin distribution would vary in different applications. The top heat layer 302-7 is a heat disposal layer, which is made of copper in one embodiment, and are made of other material in other embodiments. Persons of ordinary skill in the art should appreciate that any suitable layer configured to transfer heat from the power device die is applicable as the top heat layer.

As mentioned before, the first power device die 302-1 integrates the switches M1, M2, the driver DR1 shown in FIG. 1, and other accessory circuits not shown in FIG. 1. The plurality of pins 302-1e of the first power device die 302-1 includes at least an input pin, a switch pin, a ground pin, and a driving pin. The first switch M1 has a first terminal coupled to the input pin (corresponding to the input node 11 in FIG. 1) to receive the input voltage Vin (shown in FIG. 1), a second terminal connected to the switch pin (corresponding to a switch node S1 in FIG. 1), and a control terminal configured to receive a first driving signal G1. The second switch M2 has a first terminal connected to the switch pin, a second terminal connected to the ground pin (corresponding to the reference ground GND in FIG. 1), and a control terminal configured to receive a second driving signal G2. The driver DR1 is coupled to the driving pin to receive a phase control signal 105, and to provide the first driving signal G1 and the second driving signal G2 based on the phase control signal 105. The plurality of pins of the power device dies 302-1 and 302-2 are electrically connected to external circuits/devices/components via the bottom substrate 301.

The first winding 303-1 and the second winding 303-2 are embedded in the magnetic core 303-5 and have an upside-down “U” shape and are parallel to each other. In the example shown in FIG. 12, the first winding 303-1 has a first portion 303-1a and a second portion 303-1b connected out of the second surface 303-5b of the magnetic core 303-5, and has a middle portion 303-1c parallel to the first surface 303-5a of the magnetic core 303-5 and connecting the first portion 303-1a and the second portion 303-1b. The first portion 303-1a of the first winding 303-1 is electrically connected to the first connecting pillar 302-3 embedded within the device substrate 302 by soldering or other connecting means. The second portion 303-1b of the first winding 303-1 is electrically connected to the second connecting pillar 302-4 embedded within the device substrate 302 by soldering or other connecting means. It should be appreciated that the second winding 303-2 has the similar structure with the first winding 303-1 shown in FIG. 12.

In the embodiment of FIG. 12, the bottom substrate 301 is attached to the passive component assembly 20. In the embodiment of FIG. 12, the passive block 202 comprises a plurality of input capacitors and output capacitors. However, one with ordinary skill in the art should also understand that other passive components (e.g., resistors) and copper pillar could also be embedded into the passive block 202. As shown in FIG. 12, each input capacitors Cin, and each output capacitors Co has the terminal 31 and the terminal 32. The terminals 31-32 are used to conduct current between the substrate 201 of the passive component assembly 20 and the bottom substrate 301 of the power block 3001. One with ordinary skill in the art should understand that the number of capacitors is for illustration purpose, and any suitable number of capacitors could be included due to different applications.

The substrate 201 may be attached to a mainboard where the load (CPU, GPU, etc.) located, and there may be circuits/devices/components on the mainboard providing the input voltage Vin, the phase control signal 105, and a ground reference GND that provides a common ground for the first power device die 302-1 and the second power device die 302-2 via the ground pin. It should be appreciated that the second power device die 302-2 has the same structure as the first power device die 302-1 and is not discussed for the brevity of description.

FIG. 13 shows a bottom view 130 of the bottom substrate 301, i.e., the second surface 301-b of the bottom substrate 301, in accordance with an embodiment of the present invention.

The second surface 301-b of the bottom substrate 301 includes a signal pad area TSIG, an input pad area TVIN, a ground pad area TGND, a first output voltage pad area TVOUT1 and a second output voltage pad area TVOUT2. Each one of the pad areas includes a plurality of pads. The pads on the second surface 301-b of the bottom substrate 301 connect through to the first surface 301-a of the bottom substrate 301 using, e.g., vias and conductive traces inside the bottom substrate 301. The plurality of pads of the signal pad area TSIG are electrically connected to the signal pins of the first power device die 302-1 and the signal pins of the second power device die 302-2 respectively, like the driving pins, temperature monitoring pins, etc. The plurality of pads of the input pad area TVIN are electrically connected to the input pins of the first power device die 302-1 and the second power device die 302-2. The plurality of pads of the ground pad area TGND are electrically connected to the ground pins of the first power device die 302-1 and the second power device die 302-2. The plurality of pads of the first output voltage pad area TVOUT1 are electrically connected to the end of the second portion 303-1b of the first winding 303-1 via the second connecting pillar 302-4. The plurality of pads of the second output voltage pad area TVOUT2 are electrically connected to the end of the second portion 303-2b of the second winding 303-2 via the fourth connecting pillar 302-6. In one embodiment, the pads of the first output voltage pad area TVOUT1 and the pads of the second output voltage pad area TVOUT2 are electrically disconnected, which makes the power module 300 work as two independent converters. In some embodiments, the pads of the first output voltage pad area TVOUT1 and the pads of the second output voltage pad area TVOUT2 are electrically connected by external conductive traces or traces inside the bottom substrate, which makes the power module 300 work as a dual-phase power converter.

In one embodiment, the terminals 31 of the input capacitors Cin are electrically connected to the input pad area TVIN, and the terminals 32 of the input capacitors Cin are electrically connected to the ground pad area TGND. The terminals 31 of a first group of the output capacitors Co are electrically connected to the output pad area TVOUT1, and the terminals 32 of the first group of the output capacitors Co are electrically connected to the ground pad area TGND. Similarly, the terminals 31 of a second group of the output capacitors Co are electrically connected to the output pad area TVOUT2, and the terminals 32 of the second group of the output capacitors Co are electrically connected to the ground pad area TGND.

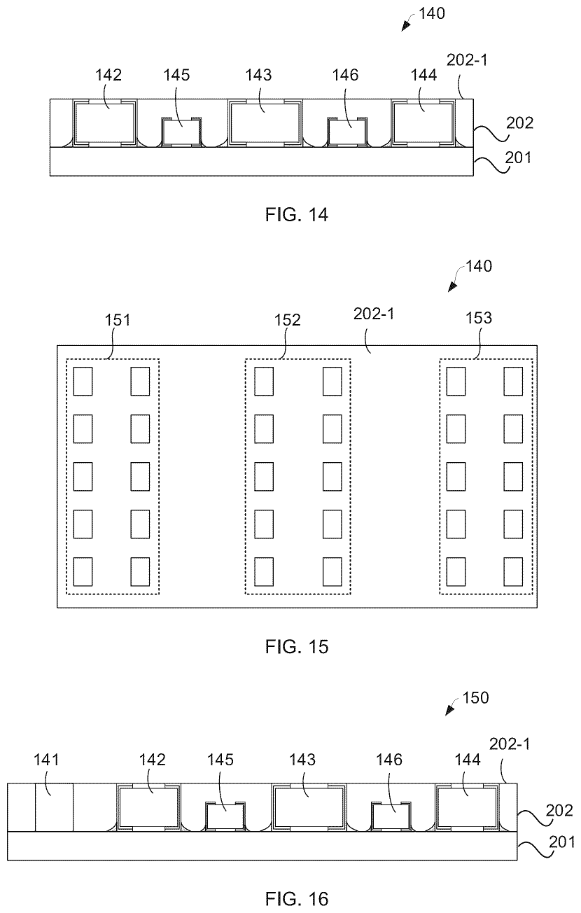

FIG. 14 shows a cross-sectional view illustrating a passive component assembly 140 in accordance with another embodiment of the present invention. The passive component assembly 140 comprises the substrate 201 and the passive block 202 mounted on the substrate 201. In addition to capacitors, other passive components could also be included in the passive block 202 with or without molding, such as inductor, resistor, copper pillar and other suitable passive components. With proper selection of the passive component height, it is flexible to choose which terminals are exposed and which terminals are hidden. In the embodiment of FIG. 14, a plurality of passive components (e.g., capacitors 142, inductors 143, and resistors 144) are embedded in the passive block 202, each of the plurality of passive components 142-144 has two terminals extended to the top surface 202-1 of the passive block 202 to form pads for conducting current from top to bottom. Each of the plurality of passive components 142-144 has a similar structure with the capacitors shown in FIGS. 3-4C. In the embodiment of FIG. 14, some smaller sized passive components (e.g., capacitor 145, resistor 146 and so on) may also be included in the passive block 202.

FIG. 15 shows a top view illustrating the passive component assembly 140 of FIG. 14 in accordance with an embodiment of the present invention. As shown in FIG. 15, the top surface of the passive block 202 has a capacitor pad area 151, an inductor pad area 152, and a resistor pad area 153. The capacitor pad area 151 has a plurality of pads corresponding to terminals of the capacitors 142, the inductor pad area 152 has a plurality of pads corresponding to ends of the inductors 143, and the resistor pad area 153 has a plurality of pads corresponding to terminals of the resistors 144.

FIG. 16 shows a cross-sectional view illustrating a passive component assembly 150 in accordance with yet another embodiment of the present invention. As shown in FIG. 16, a copper pillar 141 is further included in the passive block 202. The copper pillar 141 has a first terminal exposed on the top surface 202_1 of the passive block 202 and a second terminal mounted on the substrate 201, to conduct current between top of the passive block 202 and the substrate 201.

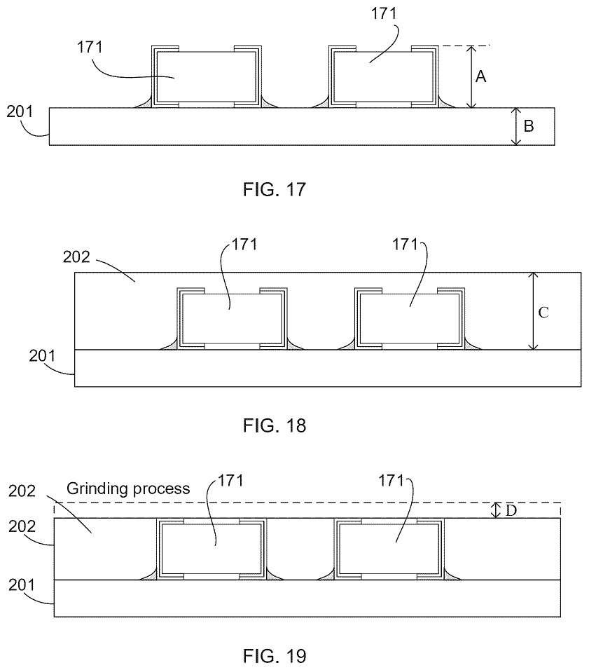

FIGS. 17-19 shows a process of fabricating a passive component assembly in accordance with an embodiment of the present invention.

Referring to FIG. 17, a substrate 201 is provided. In one embodiment, height B of the substrate 201 may be 0.2 mm to 10 mm. A plurality of passive components 171 are attached to the substrate 201. The passive components 171 may comprise at least one of a capacitor, an inductor, and a resistor. In one embodiment, height A of the passive components 171 is about 0.4 mm to 0.6 mm, typically 0.5 mm.

Subsequently, referring to FIG. 18, a molding material are filled to form the passive block 202, the passive components 171 are embedded in the passive block 202. In one embodiment, height C of the original passive block 202 in FIG. 18 may be 0.3 mm higher than height A of the passive components 171.

Subsequently, referring to FIG. 19, a grinding process is conducted on the passive block 202, such that the top side of the terminals of the passive components 171 could be exposed. In one embodiment, the grinding height D is about 0.4 mm.

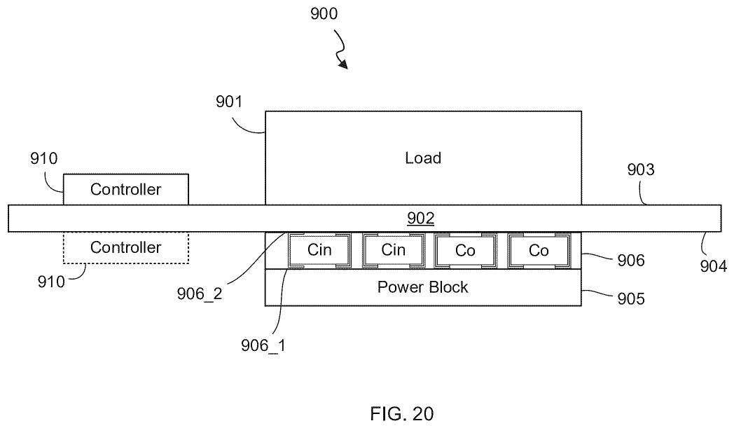

FIG. 20 shows a side view of a physical layout of a power supply system 900 in accordance with an embodiment of the present invention. FIG. 20 is not drawn to scale. In the example of FIG. 20, a power module including a power block 905 and a passive component assembly 906 provides power (e.g., an output voltage) to a load 901 (e.g., a CPU/GPU). The load 901 is disposed on a first side 903 of a motherboard 902, e.g., through associate socket and substrate. The power block 905 and the passive component assembly 906 are disposed on a second side 904 of the motherboard 902, to receive the input voltage Vin and provide the output voltage Vout. The second side 904 is opposite to the first side 903. The passive component assembly 906 has a top surface 906_1 and a bottom surface 906_2 opposite to the top surface 906_1, wherein the bottom surface 906_2 faces towards the second side 904 of the motherboard 902. In one embodiment, the passive component assembly 906 comprises a plurality of capacitors (such as input capacitors Cin, output capacitors Co), wherein terminals of the plurality of capacitors are configured as vias to conduct current between the power block 905 placed on the top surface of the passive component assembly 906 and the motherboard 902, directly or through a substrate (not shown in FIG. 20, referring the substrate 201 shown in FIGS. 2-4C). For example, each terminal of the input capacitors Cin has a side extended to the top surface 906_1 of the passive component assembly 906 to form one of a plurality of pads that electrically connected to the power block 905, and each terminal of the output capacitors Co has a side extended to the top surface 906_1 of the passive component assembly 906 to form one of a plurality of pads that electrically connected to the power block 905.

In one example, the power block 905 can be implemented by the power block 3001 as described above, and the passive component assembly 906 can be implemented by the passive component assembly 20, 140, and 150 as described above. The controller 140 may be placed on the first side 903 or on the second side 904.

While specific embodiments of the present invention have been provided, it is to be understood that these embodiments are for illustration purposes and not limiting. Many additional embodiments will be apparent to persons of ordinary skill in the art reading this disclosure.

What is claimed is:

1. A passive component assembly, comprising:
a substrate; and
a passive block having a top surface and a bottom surface which is opposite to the top surface, wherein the passive block is mounted on the substrate, and a plurality of pads are exposed on the top surface; wherein
the passive block has a plurality of capacitors, wherein each of the plurality of capacitors has two terminals, a top side of at least one terminal of the plurality of capacitors extends to the top surface to form one of the plurality of pads, and a bottom side of the at least one terminal of the plurality of capacitors extends to the bottom surface to be attached to the substrate.

2. The passive component assembly of claim 1, wherein the plurality of capacitors comprises:
an input capacitor coupled between an input node of a power module and a reference ground; wherein
the input capacitor has a first terminal and a second terminal, each of the first terminal and the second terminal of the input capacitor has a top side extended to the top surface, a bottom side attached to the substrate, and a middle side connected the top side and the bottom side.

3. The passive component assembly of claim 1, wherein the plurality of capacitors comprises:
an output capacitor coupled between an output node of the power module and a reference ground; wherein
the output capacitor has a first terminal and a second terminal, each of the first terminal and the second terminal of the output capacitor has a top side extended to the top surface, a bottom side attached to the substrate, and a middle side connected the top side and the bottom side.

4. The passive component assembly of claim 1, wherein at least one of the plurality of capacitors comprises:
a first terminal and a second terminal extended between the top surface and the bottom surface of the passive block; and
a plurality of horizontally stacked copper layers parallel to the top surface and the bottom surface of the passive block.

5. The passive component assembly of claim 4, wherein a first group of the plurality of horizontally stacked copper layers are electrically connected to the first terminal, and a second group of the plurality of horizontally stacked copper layers are electrically connected to the second terminal.

6. The passive component assembly of claim 1, wherein at least one of the plurality of capacitors comprises:
a first terminal and a second terminal extended between the top surface and the bottom surface of the passive block; wherein
each of the first terminal and the second terminal has an outer portion and an inner portion enveloped by the outer portion, the inner portion is made of a first metal material, and the outer portion is made of a second metal material.

7. The passive component assembly of claim 6, wherein the second metal material has a lower conductivity than the first metal material.

8. The passive component assembly of claim 1, wherein the top side of the at least one terminal of the plurality of capacitors extends to the top surface through a first connector, and a bottom side of the at least one terminal of the plurality of capacitors extends to the bottom surface through a second connector.

9. The passive component assembly of claim 1, wherein at least one of the plurality of capacitors comprises:
a first terminal and a second terminal extended between the top surface and the bottom surface of the passive block; and
a plurality of vertically stacked copper layers perpendicular to the top surface and the bottom surface of the passive block.

10. The passive component assembly of claim 9, wherein a first group of the plurality of vertically stacked copper layers are electrically connected to the first terminal, and a second group of the plurality of vertically stacked copper layers are electrically connected to the second terminal.

11. A power module comprising:
a power block having a pair of switches and an output inductor, wherein the output inductor has a first end coupled to a switch node formed by the pair of switches and a second end coupled to an output node of the power module; and
a passive component assembly attached to the power block, wherein the passive component assembly comprises a passive block having a plurality of capacitors, and terminals of at least one of the plurality of capacitors are configured as vias to conduct current for the power block.

12. The power module of claim 11, wherein the plurality of capacitors comprises:
an input capacitor coupled between an input node of the power module and a reference ground; wherein
the input capacitor has a first terminal and a second terminal, at least one of the first terminal and the second terminal of the input capacitor has a top side extended to a top surface of the passive block as one of a plurality of pads that electrically connected to the power block.

13. The power module of claim 11, wherein the plurality of capacitors comprises:
an output capacitor coupled between the output node of the power module and a reference ground; wherein
the output capacitor has a first terminal and a second terminal, at least one of the first terminal and the second terminal of the output capacitor has a top side extended to a top surface of the passive block as one of a plurality of pads of the passive component assembly that electrically connected to the power block.

14. The power module of claim 11, wherein the passive block has a plurality of pads exposed on a top surface, a top side of at least one terminal of the plurality of capacitors extends to a top surface of the passive block to form one of the plurality of pads that electrically connected to the power block.

15. The power module of claim 11, wherein at least one of the plurality of capacitors comprises:
a first terminal and a second terminal extended between a top surface and a bottom surface of the passive block, wherein the top surface and the bottom surface are opposite to each other; and
a plurality of horizontally stacked copper layers parallel to the top surface and the bottom surface of the passive block; wherein
a first group of the plurality of horizontally stacked copper layers are electrically connected to the first terminal, and a second group of the plurality of horizontally stacked copper layers are electrically connected to the second terminal.

16. The power module of claim 11, wherein at least one of the plurality of capacitors comprises:
a first terminal and a second terminal extended between a top surface and a bottom surface of the passive block, wherein the top surface and the bottom surface are opposite to each other; and
a plurality of vertically stacked copper layers perpendicular to the top surface and the bottom surface of the passive block; wherein
a first group of the plurality of vertically stacked copper layers are electrically connected to the first terminal, and a second group of the plurality of vertically stacked copper layers are electrically connected to the second terminal.

17. A power supply system, comprising:
a motherboard having a first side and a second side;
a load mounted on the first side of the motherboard; and
a power module attached to the second side of the motherboard, and configured to provide an output voltage to the load at an output node; wherein
the power module comprises:
a passive component assembly having a top surface and a bottom surface opposite the top surface, wherein the bottom surface faces towards the second side of the motherboard, the passive component assembly comprises a plurality of capacitors; and
a power block placed on the top surface of the passive component assembly;
wherein terminals of the plurality of capacitors are configured as vias to conduct current between the power block and the motherboard.

18. The power supply system of claim 17, wherein the plurality of capacitors comprises:
an input capacitor coupled between an input node of the power module and a reference ground; wherein
the input capacitor has a first terminal and a second terminal, at least one of the first terminal and the second terminal of the input capacitor has a side extended to the top surface of the passive component assembly to form one of a plurality of pads that electrically connected to the power block.

19. The power supply system of claim 17, wherein the plurality of capacitors comprises:
an output capacitor coupled between the output node of the power module and a reference ground; wherein
the output capacitor has a first terminal and a second terminal, at least one of the first terminal and the second terminal of the output capacitor has a side extended to the top surface of the passive component assembly to form one of a plurality of pads that electrically connected to the power block.

20. The power supply system of claim 17, wherein the power block comprises:
a pair of switches and an output inductor, wherein the output inductor has a first end coupled to a switch node formed by the pair of switches and a second end coupled to an output node of the power module.
